(19) United States
(12) Patent Application Publication
(10) Pub. No.: US 2024/0249061 A1
(43) Pub. Date: Jul. 25, 2024

(54) METHOD FOR INTEGRATED CIRCUIT DESIGN USING PIN DIRECTION OPTIMIZATION

(71) Applicant: MakinaRocks Co., Ltd., Seoul (KR)

(72) Inventors: Wooshik MYUNG, Seoul (KR); Jiyoon LIM, Seoul (KR); Seungju KIM, Seoul (KR); Wonjun YOO, Seoul (KR)

(21) Appl. No.: 18/421,808

(22) Filed: Jan. 24, 2024

(30) Foreign Application Priority Data
Jan. 25, 2023 (KR) 10-2023-0009533

(51) Int. Cl. G06F 30/392

(52) U.S. Cl. CPC G06F 30/392

(57) ABSTRACT

Disclosed is a method for designing an integrated circuit. Specifically, according to the present disclosure, a computing device identifies devices of the same type arranged in a design area, divides a device set including devices of the same type into a first subset and a second subset, rearranges devices included in the first subset based on a location of a connection site included in each device, and rearranges devices included in the second subset based on the rearranged devices included in the first subset.

### CROSS-REFERENCE TO RELATED APPLICATIONS

This application claims priority to and the benefit of Korean Patent Application No. 10-2023-0009533 filed in the Korean Intellectual Property Office on Jan. 25, 2023, the entire contents of which are incorporated herein by reference.

### BACKGROUND

### Technical Field

The present disclosure relates to a method for integrated circuit design using pin direction optimization, and particularly, to a method for integrated circuit design, which performs optimization by identifying devices of the same type among semiconductor devices arranged in an integrated circuit design area, and then rearranging the relevant devices based on a location of a connection site of the devices of the same type.

This study was conducted as part of the private intelligent information service expansion project by the Ministry of Science and ICT and the National IT Industry Promotion Agency (A0903-21-1021, Development of an AI-based semiconductor design automation system).

### Description of the Related Art

Despite technological development, a logical design of integrated circuits (ICs) is generally performed directly by engineers using tools for laying out semiconductor devices. Therefore, the logical design of integrated circuits is performed based on the engineer's experience, and the design speed is bound to vary greatly depending on the engineer's skill level. Additionally, there are limits to engineers' ability to efficiently arrange tens to millions of semiconductor devices by considering their connection relationships.

Korea Patent Registration No. 10-2474856 discloses an artificial intelligence-based integrated circuit design automation method.

### BRIEF SUMMARY

The inventors of the present disclosure have realized that it is difficult for the logical design process of an integrated circuit to maintain consistent design quality by relying on the engineer's intuition and experience. Further, since integrated circuits are greatly affected by the length of the lines connecting devices, in order to improve the performance of integrated circuits, the direction of the pins responsible for electrical connection of semiconductor devices must also be optimized. This pin direction optimization can also be performed based on the engineer's intuition and experience, but as with the arrangement of devices, there is a problem that the time required for the optimization process increases as the complexity of the circuit increases. The present disclosure is contrived in response to the above-described background art, and has been made in an effort to perform optimization by identifying devices of the same type among semiconductor devices arranged in an integrated circuit design area, and then rearranging the relevant devices based on a location of a connection site of the devices of the same type.

Meanwhile, a technical benefit to be achieved by the present disclosure is not limited to the above-mentioned technical benefit, and various technical objects can be included within the scope which is apparent to those skilled in the art from contents to be described below.

An exemplary embodiment of the present disclosure provides a method for designing an integrated circuit by a computing device. The method may include: identifying devices of the same type arranged in a design area; dividing a device set including devices of the same type into a first subset and a second subset; rearranging a device included in the first subset based on a location of a connection site included in each device; and rearranging a device included in the second subset based on the rearranged devices included in the first subset.

In an exemplary embodiment, the same type of device may be a device included in the same semiconductor device group in the design area.

In an exemplary embodiment, the device may include a macro cell.

In an exemplary embodiment, when there are multiple devices of the same type, the devices of the same type may be devices in which at least one of a name and a size of the device is the same.

In an exemplary embodiment, the dividing of the device set including devices of the same type into the first subset and the second subset may include classifying the device set into the first subset and the second subset based on location information of each device and the location information of the design area.

In an exemplary embodiment, the classifying of the device set into the first subset and the second subset based on the location information of each device and the location information of the design area may include classifying devices closest to an edge of the design area in the device set into the first subset, and classifying the rest of devices other than the first subset in the device set into the second subset.

In an exemplary embodiment, the rearranging of the devices included in the first subset based on the location of the connection site included in each device may include rearranging the devices included in the first subset based on a direction of a pin include in the each device.

In an exemplary embodiment, the rearranging of the devices included in the first subset based on the direction of the pin include in the each device may include identifying the direction of the pin of the device included in the first subset, and rearranging the devices included in the first subset based on the direction of the pin of the device included in the first subset and a location of the pin in the design area.

In an exemplary embodiment, the rearranging of the devices included in the first subset based on the direction of the pin of the device included in the first subset and the location of the pin in the design area may include rearranging the devices so that a direction of a pin in the device included in the first subset faces the inside of the design area.

In an exemplary embodiment, the rearranging of the devices included in the second subset among the devices of the same type based on the rearranged devices included in the first subset may include identifying the direction of the pin in the device included in the first subset, and rearranging the devices included in the second subset based on the direction of the pin in the device included in the first subset.

In an exemplary embodiment, the rearranging of the devices included in the second subset based on the direction of the pin in the device included in the first subset may include first rearranging a device which is neighboring to the devices included in the first subset among the devices included in the second subset sequentially based on the direction of the pin in the device included in the first subset.

In an exemplary embodiment, the first rearranging of the device which is neighboring to the devices included in the first subset among the devices included in the second subset sequentially based on the direction of the pin in the device included in the first subset may include rearranging the device which is neighboring to the device included in the first subset so that the direction of the pin faces the outside of the design area, rearranging the next device so that the direction of the pin is inside of the design area if the direction of the pin of the immediately rearranged device is outside the design area, and rearranging the next device so that the direction of the pin is outside the design area if the direction of the pin of the immediately rearranged device is inside of the design area.

Another exemplary embodiment of the present disclosure provides a computer program which allows a computing device to perform operations for designing an integrated circuit. The operations may include: an operation of identifying devices of the same type arranged in a design area; an operation of dividing a device set including devices of the same type into a first subset and a second subset; an operation of rearranging a device included in the first subset based on a location of a connection site included in each device; and an operation of rearranging a device included in the second subset based on the rearranged device included in the first subset.

Still another exemplary embodiment of the present disclosure provides a computing device for designing an integrated circuit. The computing device may include a processor including one or more cores; and a memory, and the processor may identify devices of the same type arranged in a design area, divide a device set including devices of the same type into a first subset and a second subset, rearrange devices included in the first subset based on a location of a connection site included in each device, and rearrange devices included in the second subset based on the rearranged devices included in the first subset.

The present disclosure has the effect of efficiently designing integrated circuits. For example, according to the present disclosure, optimization can be performed by identifying devices of the same type among semiconductor devices arranged in an integrated circuit design area, and then rearranging the relevant devices based on a location of a connection site of the devices of the same type. As a result, the present disclosure allows pin optimization to be performed much faster than using other algorithms, while being intuitive and without adversely affecting performance.

### BRIEF DESCRIPTION OF THE SEVERAL VIEWS OF THE DRAWINGS

FIG. 1 is a block diagram of a computing device for designing an integrated circuit according to an exemplary embodiment of the present disclosure.

FIG. 2 is a flowchart illustrating a process of designing an integrated circuit according to an exemplary embodiment of the present disclosure.

FIG. 3 is a conceptual view illustrating a semiconductor device according to an exemplary embodiment of the present disclosure.

FIG. 4 is a conceptual view illustrating semiconductor devices arranged in a design area according to an exemplary embodiment of the present disclosure.

FIG. 5 is a conceptual view illustrating semiconductor devices belonging to the same group according to an exemplary embodiment of the present disclosure.

FIG. 6A-6D are conceptual views illustrating a process of rearranging semiconductor devices included in a first subset and a second subset according to an exemplary embodiment of the present disclosure.

FIG. 7 is a schematic view illustrating a network function according to an exemplary embodiment of the present disclosure.

FIG. 8 is a simple and normal schematic view of an exemplary computing environment in which the exemplary embodiments of the present disclosure may be implemented.

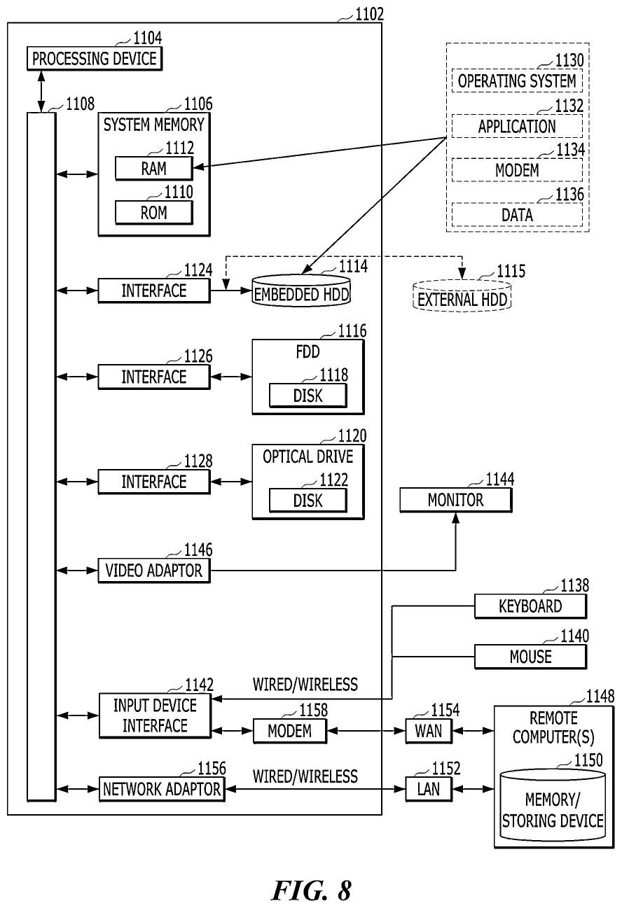

### DETAILED DESCRIPTION

The present disclosure provides a method for performing optimization by identifying devices of the same type among semiconductor devices arranged in an integrated circuit design area, and then rearranging the relevant devices based on a location of a connection site of the devices of the same type.

Various exemplary embodiments are described with reference to the drawings. In the present specification, various descriptions are presented for understanding the present disclosure. However, it is obvious that the exemplary embodiments may be carried out even without a particular description.

Terms, “component”, “module”, “system”, and the like used in the present specification indicate a computer-related entity, hardware, firmware, software, a combination of software and hardware, or execution of software. For example, a component may be a procedure executed in a processor, a processor, an object, an execution thread, a program, and/or a computer, but is not limited thereto. For example, both an application executed in a computing device and a computing device may be components. One or more components may reside within a processor and/or an execution thread. One component may be localized within one computer. One component may be distributed between two or more computers. Further, the components may be executed by various computer readable media having various data structures stored therein. For example, components may communicate through local and/or remote processing according to a signal (for example, data transmitted to another system through a network, such as the Internet, through data and/or a signal from one component interacting with another component in a local system and a distributed system) having one or more data packets.

Further, a term “or” intends to mean comprehensive “or” not exclusive “or”. That is, unless otherwise specified or when it is unclear in context, “X uses A or B” intends to mean one of the natural comprehensive substitutions. That is, in the case where X uses A; X uses B; or, X uses both A and B, “X uses A or B” may apply to either of these cases. Further, a term “and/or” used in the present specification shall be understood to designate and include all of the possible combinations of one or more items among the listed relevant items.

Further, a term “include” and/or “including” shall be understood as meaning that a corresponding characteristic and/or a constituent element exists. Further, it shall be understood that a term “include” and/or “including” means that the existence or an addition of one or more other characteristics, constituent elements, and/or a group thereof is not excluded. Further, unless otherwise specified or when it is unclear that a single form is indicated in context, the singular shall be construed to generally mean “one or more” in the present specification and the claims.

Further, the term “at least one of A and B” should be interpreted to mean “the case including only A”, “the case including only B”, and “the case where A and B are combined”.

Those skilled in the art shall recognize that the various illustrative logical blocks, configurations, modules, circuits, means, logic, and algorithm operations described in relation to the exemplary embodiments additionally disclosed herein may be implemented by electronic hardware, computer software, or in a combination of electronic hardware and computer software. In order to clearly exemplify interchangeability of hardware and software, the various illustrative components, blocks, configurations, means, logic, modules, circuits, and operations have been generally described above in the functional aspects thereof. Whether the functionality is implemented as hardware or software depends on a specific application or design restraints given to the general system. Those skilled in the art may implement the functionality described by various methods for each of the specific applications. However, it shall not be construed that the determinations of the implementation deviate from the range of the contents of the present disclosure.

The description about the presented exemplary embodiments is provided so as for those skilled in the art to use or carry out the present disclosure. Various modifications of the exemplary embodiments will be apparent to those skilled in the art. General principles defined herein may be applied to other exemplary embodiments without departing from the scope of the present disclosure. Therefore, the present disclosure is not limited to the exemplary embodiments presented herein. The present disclosure shall be interpreted within the broadest meaning range consistent to the principles and new characteristics presented herein.

In the present disclosure, a design area may mean a canvas in the field of integrated circuit design. The canvas may refer to a base material on which individual semiconductor devices are arranged to configure an integrated circuit.

In the present disclosure, a semiconductor device is an object made using a semiconductor material and may refer to an object that performs a specific role within an electronic component. For example, individual devices, memory, system integrated circuits (ICs), etc., may be included in the semiconductor device.

In the present disclosure, a macro cell is a type of semiconductor device that constitutes an integrated circuit, and may refer to a logic block that performs a complex function within the integrated circuit. Typically, the macro cell is larger than a standard cell, which is another component of the integrated circuit, and may have a rectangular shape.

In the present disclosure, a pin is an area that exists in the semiconductor device or other type of electronic component, and may refer to an area that may receive or output an electrical signal within a circuit.

In the present disclosure, a basic design process of the integrated circuit may be configured in such a manner that the processor 110 of the computing device 100 arranges the semiconductor device including a macro cell on the design area of the integrated circuit in a program, and then performs the remaining design process by a human or artificial intelligence model. At this time, when arranging semiconductor devices, devices that are closely related to each other may be grouped according to a predetermined criterion. At this time, each group may have a horizontal relationship, or a plurality of groups may be included within one group. Thereafter, the processor 110 may arrange semiconductor devices on the design area of the integrated circuit so that semiconductor devices belonging to the same group tend to be neighboring to each other according to the grouping result.

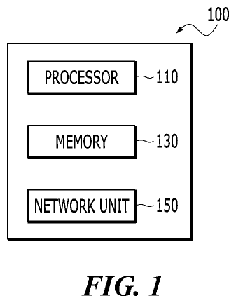

FIG. 1 is a block diagram of a computing device for designing a semiconductor according to an exemplary embodiment of the present disclosure.

A configuration of the computing device 100 illustrated in FIG. 1 is only an example shown through simplification. In an exemplary embodiment of the present disclosure, the computing device 100 may include other components for performing a computing configuration of the computing device 100 and only some of the disclosed components may constitute the computing device 100.

The computing device 100 may include a processor 110, a memory 130, and a network unit 150.

The processor 110 may be constituted by one or more cores, and include processors for data analysis and deep learning, such as a central processing unit (CPU), a general purpose graphics processing unit (GPGPU), a tensor processing unit (TPU), etc., of the computing device. The processor 110 may read a computer program stored in the memory 130 and process data for machine learning according to an exemplary embodiment of the present disclosure. According to an exemplary embodiment of the present disclosure, the processor 110 may perform an operation for learning the neural network. The processor 110 may perform calculations for learning the neural network, which include processing of input data for learning in deep learning (DL), extracting a feature in the input data, calculating an error, updating a weight of the neural network using backpropagation, and the like.

At least one of the CPU, the GPGPU, and the TPU of the processor 110 may process learning of the network function. For example, the CPU and the GPGPU may process the learning of the network function and data classification using the network function jointly. In addition, in an exemplary embodiment of the present disclosure, the learning of the network function and the data classification using the network function may be processed by using processors of a plurality of computing devices together. In addition, the computer program performed by the computing device according to an exemplary embodiment of the present disclosure may be a CPU, GPGPU, or TPU executable program.

In the present disclosure, a basic design process of the integrated circuit may be configured in such a manner that the processor 110 of the computing device 100 arranges the semiconductor device including a macro cell on the design area of the integrated circuit in a program, and then performs the remaining design process by a human or artificial intelligence model. At this time, when arranging semiconductor devices, devices that are closely related to each other may be grouped according to a predetermined criterion. Thereafter, the semiconductor devices may be arranged on the design area of the semiconductor so that semiconductor devices belonging to the same group are neighboring to each other according to the grouping result.

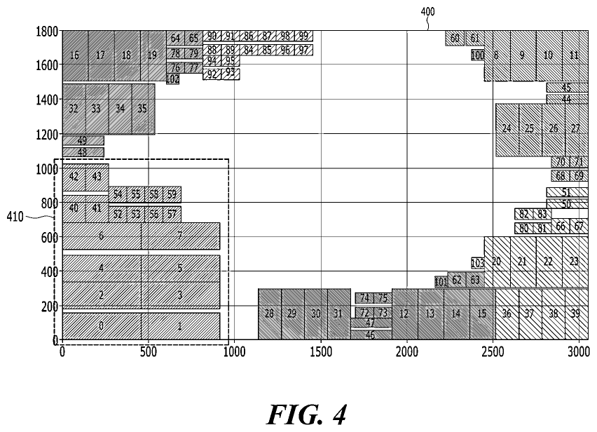

The processor 110 may identify devices of the same type arranged in the design area of the integrated circuit. At this time, the processor 110 may identify the same semiconductor device group in the design area and identify devices of the same type within one group. In particular, in the present disclosure, the same type of device may mean the same type of device included in the same semiconductor device group in the design area. A specific method for identifying devices of the same type will be described later with reference to FIG. 4.

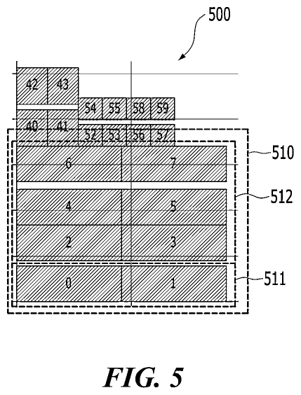

The processor 110 may divide a device set including devices of the same type into a first subset and a second subset. At this time, location information of each device and location information of the design area may be used as a standard for dividing the first subset and the second subset, and a specific division method will be described later with reference to FIG. 5.

The processor 110 may rearrange the device included in the first subset based on the location of the connection site included in the first subset. At this time, the connection site may mean a pin present in each device, and the processor 110 may rearrange the devices using direction information of the pin of each device and location information of the design area. In the present disclosure, rearranging a device may include either rotating, flipping, or changing the position of the device.

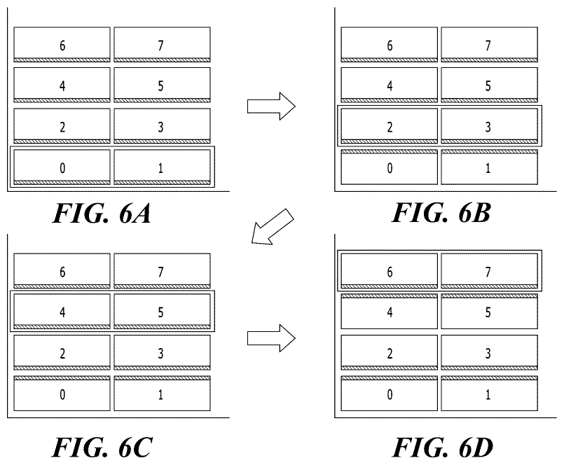

Thereafter, the processor 110 may rearrange the device included in the second subset based on the rearranged device included in the first subset. A specific process of rearranging the devices included in the first subset and the second subset will be described later with reference to FIGS. 6A-6D.

According to an exemplary embodiment of the present disclosure, the memory 130 may include at least one type of storage medium of a flash memory type storage medium, a hard disk type storage medium, a multimedia card micro type storage medium, a card type memory (for example, an SD or XD memory, or the like), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk. The computing device 100 may operate in connection with a web storage performing a storing function of the memory 130 on the Internet. The description of the memory is just an example and the present disclosure is not limited thereto.

The network unit 150 according to several embodiments of the present disclosure may use various wired communication systems, such as a Public Switched Telephone Network (PSTN), an x Digital Subscriber Line (xDSL), a Rate Adaptive DSL (RADSL), a Multi Rate DSL (MDSL), a Very High Speed DSL (VDSL), a Universal Asymmetric DSL (UADSL), a High Bit Rate DSL (HDSL), and a local area network (LAN).

The network unit 150 presented in the present specification may use various wireless communication systems, such as Code Division Multi Access (CDMA), Time Division Multi Access (TDMA), Frequency Division Multi Access (FDMA), Orthogonal Frequency Division Multi Access (OFDMA), Single Carrier-FDMA (SC-FDMA), and other systems.

The network unit 150 presented in the present specification may use various wireless communication systems

The techniques described herein may be used not only in the networks mentioned above, but also in other networks.

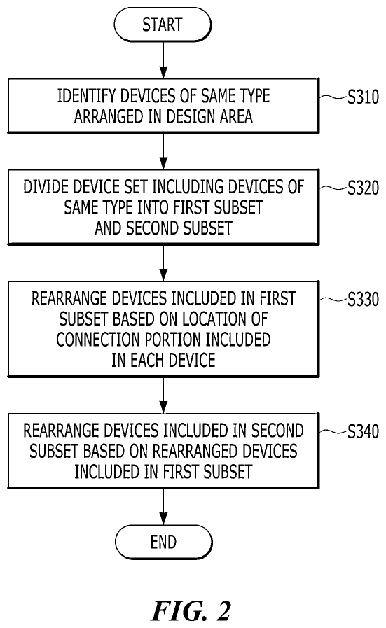

FIG. 2 is a flowchart illustrating a process of designing an integrated circuit according to an exemplary embodiment of the present disclosure. According to FIG. 2, the process of designing an integrated circuit according to the present disclosure may include a step S210 of identifying devices of the same type arranged in a design area, a step S220 of dividing a device set including devices of the same type into a first subset and a second subset, a step S230 of rearranging a device included in the first subset based on a location of a connection site included in each device, and a step S240 of rearranging a device included in the second subset based on the rearranged devices included in the first subset.

In step S210, the processor 110 may identify the devices of the same type arranged in the design area of the integrated circuit. In this case, the same type of device may a device included in the same semiconductor device group in the design area. If there are multiple devices of the same type identified, the devices may have devices in which at least one of a name and a size of the device is the same. A specific example of identifying the devices of the same type will be described later with reference to FIG. 4.

In step S220, the processor 110 may divide the device set including the devices of the same type into the first subset and the second subset. At this time, location information of each device and the location information of the design area may be used as a standard for classifying the first subset and the second subset. For example, in the device set, devices closest to an edge of the design area may be classified into the first subset, and in the device set, the rest of the devices other than the devices included in the first subset may be classified into the second subset. A specific example of dividing the device set will be described later with reference to FIG. 5.

In step S230, the processor 110 may rearrange the devices included in the first subset based on the location of the connection site included in each device. At this time, the connection site may a pin area present in each semiconductor device, and the processor 110 may rearrange the devices included in the first subset so that a direction of a pin in each device faces the inside of the design area based on the direction of the pin. A specific example of rearranging the devices included in the first subset will be described later with reference to FIGS. 6A-6D.

In step S240, the processor 110 may rearrange the devices included in the second subset based on the rearranged devices included in the first subset. In step S230, the devices included in the first subset are rearranged so that the direction of the pins faces inside of the design area, so the processor 110 may first rearrange a device which is neighboring to the devices included in the first subset among the devices included in the second subset sequentially. For example, the devices included in the second subset may be rearranged in a such a manner that if the direction of the pin of the immediately rearranged device is outside the design area, the processor 110 may rearrange the next device so that the direction of the pin is inside of the design area, and if the direction of the pin of the immediately rearranged device is inside of the design area, a next device is rearranged so that the direction of the pin is outside the design area. A specific example of rearranging the devices included in the second subset will be described later with reference to FIGS. 6A-6D.

Typically, semiconductor devices of the same size or name are likely to be arranged (by humans or models) to have a close relationship with each other in the final completed circuit. Therefore, when rearranging semiconductor devices existing in the design area through the above process, devices of the same type, that is, devices that are closely related to each other, may be arranged with the directions of the pins facing each other or facing away from each other. When the directions of the pins of two devices face each other, the length of the line for processing signals going to and from the two devices is shortened, so the performance of the finally completed integrated circuit can be further improved.

To perform the above pin optimization, an automated algorithm using a Half-Perimeter Wire Length (HPWL) calculation may be used, but the algorithm takes a relatively long time to produce a result and require a large amount of computation. As in the present disclosure, when semiconductor devices of the same type are rearranged so that the directions of the pins are facing each other or are facing away from each other, an optimization result may be obtained much faster than a separate pin optimization algorithm without significantly deteriorating performance.

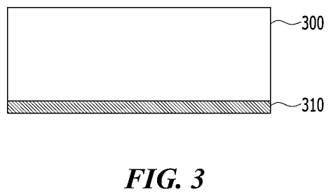

FIG. 3 is a conceptual view illustrating a semiconductor device according to an exemplary embodiment of the present disclosure.

In the present disclosure, the semiconductor device 300 may have the same meaning as a macro cell. A typical macro cell 300 may include a pin area 310 in the device. The pin area 310 can receive or output an electrical signal. In this way, signals between macro cells or between macro cells and standard cells may be exchanged through the pin area. As mentioned above, macro cells of the same type tend to be closely related within a completed integrated circuit. That is, macro cells of the same type may have a large number of lines connecting the macro cells. When the pin-to-pin distance between macro cells of the same type increases, the length of the line connecting the macro cells also increases, and thus the performance of the finally completed integrated circuit may deteriorate. Therefore, if the integrated circuit is designed by optimizing the direction in which the pins of each macro cell face, the performance of the integrated circuit can be improved.

FIG. 4 is a conceptual view illustrating semiconductor devices arranged in a design area according to an exemplary embodiment of the present disclosure.

As each semiconductor device is arranged within the entire design area 400, a rectangle marked with a number may mean one semiconductor device. At this time, semiconductor devices marked in the same color may be classified as belonging to the same group. For example, among the semiconductor devices present in the entire design area 400, devices 0, 1, 2, 3, 4, 5, 6, 7, 40, 41, 42, 43, 52, 53, 54, 55, 56, 57, 58, and 59 may belong to one group 410.

The group may consist of a plurality of devices and may include various types of devices. At this time, if the characteristics, such as the name of the device or the size of the device, are similar, the processor 110 may classify the devices as the same type. Referring to FIG. 4, devices 0, 1, 2, 3, 4, 5, 6, and 7 in one group 410 can be classified as first type devices, and devices 40, 41, 42, and 43 may be classified as second type devices, and devices 52, 53, 54, 55, 56, 57, 58, and 59 may be classified as third type devices. In the present disclosure, there must not always be a plurality of devices belonging to the same type, and it may be assumed that there is only one device of the same type, such as device 101 in FIG. 4.

FIG. 5 is a conceptual view illustrating semiconductor devices belonging to the same group according to an exemplary embodiment of the present disclosure.

As described with reference to FIG. 4, multiple types of device sets may exist within the same group. The device set 510 including devices of the same type as device 0 may be divided into a first subset 511 including device 0 and device 1, which are the devices closest to an edge 520 of the design area, and a second subset 512 which includes devices 2, 3, 4, 5, 6, and 7 which are the remaining devices.

FIGS. 6A-6D are conceptual views illustrating a process of rearranging semiconductor devices included in a first subset and a second subset according to an exemplary embodiment of the present disclosure.

FIGS. 6A-6D are exemplary diagrams showing only a portion of the entire design area, and rearrangement as shown in FIGS. 6A-6D may be performed on all groups and all types of devices existing on the integrated circuit design area.

Referring to FIG. 6A, the initial arrangement of the devices before rearranging them may be as shown in FIG. 6A. In this case, devices 0 and 1, which are the devices closest to the design area, may be classified into the first subset, and, devices 2, 3, 4, 5, 6, and 7, which are the remaining devices, may be classified into the second subset.

In an embodiment of the present disclosure, rearrangement of the devices included in the first subset may be performed first. At this time, the processor 110 may rearrange the direction of the pins of devices included in the first subset to face inside of the design area. In the initial arrangement shown in FIG. 6A, the direction of the pins of devices 0 and 1 belonging to the first subset are oriented toward the outside of the design area, and the pins of devices 0 and 1 may be rearranged so that the location of the pin of each device faces the inside through a method such as rotation. As a result, after the first subset is rearranged, the first subset may have the same shape as shown in FIG. 6B.

In an embodiment of the present disclosure, after the devices included in the first subset are rearranged, the processor 110 may first rearrange a device neighboring to the device included in the first subset among the devices included in the second subset sequentially based on the direction of the pins of the devices included in the first subset. At this time, if the direction of the pin of the immediately rearranged device is outside the design area, the processor 110 may rearrange the next device so that the direction of the pin is inside of the design area, and if the direction of the pin of the immediately rearranged device is inside of the design area, the processor 110 may rearrange the next device so that the direction of the pin is outside the design area.

In the exemplary case illustrated in FIG. 6, since the devices included in the first subset from the initial arrangement (see FIG. 6A) are rearranged, devices 2 and 3, which are devices immediately neighboring to the first subset in FIG. 6B, may be rearranged. Since the direction of the pins of devices 0 and 1 rearranged immediately before devices 2 and 3 is inside of the design area, the processor 110 may rearrange devices 2 and 3 so that the direction of the pins is outside the design area.

After devices 2 and 3 are rearranged, in FIG. 6C the processor 110 may rearrange devices 4 and 5 neighboring thereto. Since the direction of the pins of devices 2 and 3 rearranged immediately before devices 4 and 5 faces the outside of the design area, the processor 110 may rearrange devices 4 and 5 so that the direction of the pins is inside of the design area.

After devices 4 and 5 are rearranged, in FIG. 6D the processor 110 may rearrange devices 6 and 7 neighboring thereto. Since the direction of the pins of devices 4 and 5 rearranged immediately before devices 6 and 7 faces the outside of the design area, the processor 110 may rearrange devices 6 and 7 so that the direction of the pins is inside of the design area.

Through the above process, the processor 110 may rearrange all device sets of the same type according to the criterion. As a result, in the final arrangement as shown in FIG. 6D, the pins of devices 0, 1, 2, and 3 face each other, and the pins of devices 4, 5, 6, and 7 face each other. Since the distance between pins is close, it may be easily predicted that in a circuit of the same structure, the total length of the lines connecting each device will be shorter in the final arrangement shown in FIG. 6D than in the initial arrangement shown in FIG. 6A.

In this way, through this disclosure, the length of the line connecting each device in the integrated circuit design area can be shortened by optimizing the direction of the pin, which has the effect of increasing the performance of the integrated circuit.

In addition, there is also effect in that instead of performing pin direction optimization based on numbers such as HPWL for the entire integrated circuit, the pin direction is optimized based on rules that match intuition, dramatically reducing the time and computational resources required in the optimization process.

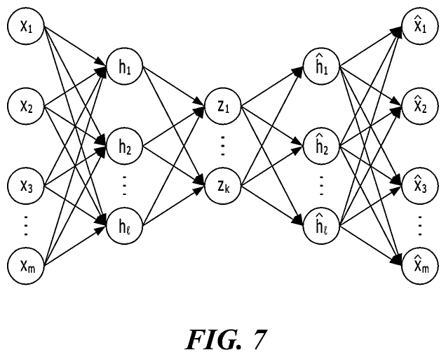

FIG. 7 is a schematic diagram illustrating a network function according to the embodiment of the present disclosure.

Throughout the present specification, the meanings of a calculation model, a nerve network, the network function, and the neural network may be interchangeably used. The neural network may be formed of a set of interconnected calculation units which are generally referred to as “nodes”. The “nodes” may also be called “neurons”. The neural network consists of one or more nodes. The nodes (or neurons) configuring the neural network may be interconnected by one or more links.

In the neural network, one or more nodes connected through the links may relatively form a relationship of an input node and an output node. The concept of the input node is relative to the concept of the output node, and a predetermined node having an output node relationship with respect to one node may have an input node relationship in a relationship with another node, and a reverse relationship is also available. As described above, the relationship between the input node and the output node may be generated based on the link. One or more output nodes may be connected to one input node through a link, and a reverse case may also be valid.

In the relationship between an input node and an output node connected through one link, a value of the output node data may be determined based on data input to the input node. Herein, a link connecting the input node and the output node may have a weight. The weight is variable, and in order for the neural network to perform a desired function, the weight may be varied by a user or an algorithm. For example, when one or more input nodes are connected to one output node by links, respectively, a value of the output node may be determined based on values input to the input nodes connected to the output node and weights set in the link corresponding to each of the input nodes.

As described above, in the neural network, one or more nodes are connected with each other through one or more links to form a relationship of an input node and an output node in the neural network. A characteristic of the neural network may be determined according to the number of nodes and links in the neural network, a correlation between the nodes and the links, and a value of the weight assigned to each of the links. For example, when there are two neural networks in which the numbers of nodes and links are the same and the weight values between the links are different, the two neural networks may be recognized to be different from each other.

The neural network may consist of a set of one or more nodes. A subset of the nodes configuring the neural network may form a layer. Some of the nodes configuring the neural network may form one layer on the basis of distances from an initial input node. For example, a set of nodes having a distance of n from an initial input node may form n layers. The distance from the initial input node may be defined by the minimum number of links, which need to be passed to reach a corresponding node from the initial input node. However, the definition of the layer is arbitrary for the description, and a degree of the layer in the neural network may be defined by a different method from the foregoing method. For example, the layers of the nodes may be defined by a distance from a final output node.

The initial input node may mean one or more nodes to which data is directly input without passing through a link in a relationship with other nodes among the nodes in the neural network. Otherwise, the initial input node may mean nodes which do not have other input nodes connected through the links in a relationship between the nodes based on the link in the neural network. Similarly, the final output node may mean one or more nodes that do not have an output node in a relationship with other nodes among the nodes in the neural network. Further, the hidden node may mean nodes configuring the neural network, not the initial input node and the final output node.

In the neural network according to the embodiment of the present disclosure, the number of nodes of the input layer may be the same as the number of nodes of the output layer, and the neural network may be in the form that the number of nodes decreases and then increases again from the input layer to the hidden layer. Further, in the neural network according to another embodiment of the present disclosure, the number of nodes of the input layer may be smaller than the number of nodes of the output layer, and the neural network may be in the form that the number of nodes decreases from the input layer to the hidden layer. Further, in the neural network according to another embodiment of the present disclosure, the number of nodes of the input layer may be larger than the number of nodes of the output layer, and the neural network may be in the form that the number of nodes increases from the input layer to the hidden layer. The neural network according to another embodiment of the present disclosure may be the neural network in the form in which the foregoing neural networks are combined.

A deep neural network (DNN) may mean the neural network including a plurality of hidden layers, in addition to an input layer and an output layer. When the DNN is used, it is possible to recognize a latent structure of data. That is, it is possible to recognize latent structures of photos, texts, videos, voice, and music (for example, what objects are in the photos, what the content and emotions of the texts are, and what the content and emotions of the voice are). The DNN may include a convolutional neural network (CNN), a recurrent neural network (RNN), an auto encoder, Generative Adversarial Networks (GAN), a Long Short-Term Memory (LSTM), a transformer, a restricted Boltzmann machine (RBM), a deep belief network (DBN), a Q network, a U network, a Siamese network, a Generative Adversarial Network (GAN), and the like. The foregoing description of the deep neural network is merely illustrative, and the present disclosure is not limited thereto.

In the embodiment of the present disclosure, the network function may include an auto encoder. The auto encoder may be one type of artificial neural network for outputting output data similar to input data. The auto encoder may include at least one hidden layer, and the odd-numbered hidden layers may be disposed between the input/output layers. The number of nodes of each layer may decrease from the number of nodes of the input layer to an intermediate layer called a bottleneck layer (encoding), and then be expanded symmetrically with the decrease from the bottleneck layer to the output layer (symmetric with the input layer). The auto encoder may perform a nonlinear dimension reduction. The number of input layers and the number of output layers may correspond to the dimensions after preprocessing of the input data. In the auto encoder structure, the number of nodes of the hidden layer included in the encoder decreases as a distance from the input layer increases. When the number of nodes of the bottleneck layer (the layer having the smallest number of nodes located between the encoder and the decoder) is too small, the sufficient amount of information may not be transmitted, so that the number of nodes of the bottleneck layer may be maintained in a specific number or more (for example, a half or more of the number of nodes of the input layer and the like).

The neural network may be trained by at least one scheme of supervised learning, unsupervised learning, semi-supervised learning, and reinforcement learning. The training of the neural network may be a process of applying knowledge for the neural network to perform a specific operation to the neural network.

The neural network may be trained in a direction of minimizing an error of an output. In the training of the neural network, training data is repeatedly input to the neural network and an error of an output of the neural network for the training data and a target is calculated, and the error of the neural network is back-propagated in a direction from an output layer to an input layer of the neural network in order to decrease the error, and a weight of each node of the neural network is updated. In the case of the supervised learning, training data labelled with a correct answer (that is, labelled training data) is used, in each training data, and in the case of the unsupervised learning, a correct answer may not be labelled to each training data. That is, for example, the training data in the supervised learning for data classification may be data, in which category is labelled to each of the training data. The labelled training data is input to the neural network and the output (category) of the neural network is compared with the label of the training data to calculate an error. For another example, in the case of the unsupervised learning related to the data classification, training data that is the input is compared with an output of the neural network, so that an error may be calculated. The calculated error is back-propagated in a reverse direction (that is, the direction from the output layer to the input layer) in the neural network, and a connection weight of each of the nodes of the layers of the neural network may be updated according to the backpropagation. A change amount of the updated connection weight of each node may be determined according to a learning rate. The calculation of the neural network for the input data and the backpropagation of the error may configure a learning epoch. The learning rate is differently applicable according to the number of times of repetition of the learning epoch of the neural network. For example, at the initial stage of the learning of the neural network, a high learning rate is used to make the neural network rapidly secure performance of a predetermined level and improve efficiency, and at the latter stage of the learning, a low learning rate is used to improve accuracy.

In the training of the neural network, the training data may be generally a subset of actual data (that is, data to be processed by using the trained neural network), and thus an error for the training data is decreased, but there may exist a learning epoch, in which an error for the actual data is increased. Overfitting is a phenomenon, in which the neural network excessively learns training data, so that an error for actual data is increased. For example, a phenomenon, in which the neural network learning a cat while seeing a yellow cat cannot recognize cats, other than a yellow cat, as cats, is a sort of overfitting. Overfitting may act as a reason of increasing an error of a machine learning algorithm. In order to prevent overfitting, various optimizing methods may be used. In order to prevent overfitting, a method of increasing training data, a regularization method, a dropout method of inactivating a part of nodes of the network during the training process, a method using a bath normalization layer, and the like may be applied.

In the meantime, according to an embodiment of the present disclosure, a computer readable medium storing a data structure is disclosed.

The data structure may refer to organization, management, and storage of data that enable efficient access and modification of data. The data structure may refer to organization of data for solving a specific problem (for example, data search, data storage, and data modification in the shortest time). The data structure may also be defined with a physical or logical relationship between the data elements designed to support a specific data processing function. A logical relationship between data elements may include a connection relationship between user defined data elements. A physical relationship between data elements may include an actual relationship between the data elements physically stored in a computer readable storage medium (for example, a permanent storage device). In particular, the data structure may include a set of data, a relationship between data, and a function or a command applicable to data. Through the effectively designed data structure, the computing device may perform a calculation while minimally using resources of the computing device. In particular, the computing device may improve efficiency of calculation, reading, insertion, deletion, comparison, exchange, and search through the effectively designed data structure.

The data structure may be divided into a linear data structure and a non-linear data structure according to the form of the data structure. The linear data structure may be the structure in which only one data is connected after one data. The linear data structure may include a list, a stack, a queue, and a deque. The list may mean a series of dataset in which order exists internally. The list may include a linked list. The linked list may have a data structure in which data is connected in a method in which each data has a pointer and is linked in a single line. In the linked list, the pointer may include information about the connection with the next or previous data. The linked list may be expressed as a single linked list, a double linked list, and a circular linked list according to the form. The stack may have a data listing structure with limited access to data. The stack may have a linear data structure that may process (for example, insert or delete) data only at one end of the data structure. The data stored in the stack may have a data structure (Last In First Out, LIFO) in which the later the data enters, the sooner the data comes out. The queue is a data listing structure with limited access to data, and may have a data structure (First In First Out, FIFO) in which the later the data is stored, the later the data comes out, unlike the stack. The deque may have a data structure that may process data at both ends of the data structure.

The non-linear data structure may be the structure in which the plurality of data is connected after one data. The non-linear data structure may include a graph data structure. The graph data structure may be defined with a vertex and an edge, and the edge may include a line connecting two different vertexes. The graph data structure may include a tree data structure. The tree data structure may be the data structure in which a path connecting two different vertexes among the plurality of vertexes included in the tree is one. That is, the tree data structure may be the data structure in which a loop is not formed in the graph data structure.

Throughout the present specification, a calculation model, a nerve network, the network function, and the neural network may be used with the same meaning. Hereinafter, the terms of the calculation model, the nerve network, the network function, and the neural network are unified and described with a neural network. The data structure may include a neural network. Further, the data structure including the neural network may be stored in a computer readable medium. The data structure including the neural network may also include preprocessed data for processing by the neural network, data input to the neural network, a weight of the neural network, a hyper-parameter of the neural network, data obtained from the neural network, an active function associated with each node or layer of the neural network, and a loss function for training of the neural network. The data structure including the neural network may include predetermined configuration elements among the disclosed configurations. That is, the data structure including the neural network may include the entirety or a predetermined combination of pre-processed data for processing by neural network, data input to the neural network, a weight of the neural network, a hyper parameter of the neural network, data obtained from the neural network, an active function associated with each node or layer of the neural network, and a loss function for training the neural network. In addition to the foregoing configurations, the data structure including the neural network may include predetermined other information determining a characteristic of the neural network. Further, the data structure may include all type of data used or generated in a computation process of the neural network, and is not limited to the foregoing matter. The computer readable medium may include a computer readable recording medium and/or a computer readable transmission medium. The neural network may be formed of a set of interconnected calculation units which are generally referred to as “nodes”. The “nodes” may also be called “neurons.” The neural network consists of one or more nodes.

The data structure may include data input to the neural network. The data structure including the data input to the neural network may be stored in the computer readable medium. The data input to the neural network may include training data input in the training process of the neural network and/or input data input to the training completed neural network. The data input to the neural network may include data that has undergone pre-processing and/or data to be pre-processed. The pre-processing may include a data processing process for inputting data to the neural network. Accordingly, the data structure may include data to be pre-processed and data generated by the pre-processing. The foregoing data structure is merely an example, and the present disclosure is not limited thereto.

The data structure may include a weight of the neural network (in the present specification, weights and parameters may be used with the same meaning), Further, the data structure including the weight of the neural network may be stored in the computer readable medium. The neural network may include a plurality of weights. The weight is variable, and in order for the neural network to perform a desired function, the weight may be varied by a user or an algorithm. For example, when one or more input nodes are connected to one output node by links, respectively, the output node may determine a data value output from the output node based on values input to the input nodes connected to the output node and the weight set in the link corresponding to each of the input nodes. The foregoing data structure is merely an example, and the present disclosure is not limited thereto.

For a non-limited example, the weight may include a weight varied in the neural network training process and/or the weight when the training of the neural network is completed. The weight varied in the neural network training process may include a weight at a time at which a training cycle starts and/or a weight varied during a training cycle. The weight when the training of the neural network is completed may include a weight of the neural network completing the training cycle. Accordingly, the data structure including the weight of the neural network may include the data structure including the weight varied in the neural network training process and/or the weight when the training of the neural network is completed. Accordingly, it is assumed that the weight and/or a combination of the respective weights are included in the data structure including the weight of the neural network. The foregoing data structure is merely an example, and the present disclosure is not limited thereto.

The data structure including the weight of the neural network may be stored in the computer readable storage medium (for example, a memory and a hard disk) after undergoing a serialization process. The serialization may be the process of storing the data structure in the same or different computing devices and converting the data structure into a form that may be reconstructed and used later. The computing device may serialize the data structure and transceive the data through a network. The serialized data structure including the weight of the neural network may be reconstructed in the same or different computing devices through deserialization. The data structure including the weight of the neural network is not limited to the serialization. Further, the data structure including the weight of the neural network may include a data structure (for example, in the non-linear data structure, B-Tree, Trie, m-way search tree, AVL tree, and Red-Black Tree) for improving efficiency of the calculation while minimally using the resources of the computing device. The foregoing matter is merely an example, and the present disclosure is not limited thereto.

The data structure may include a hyper-parameter of the neural network. The data structure including the hyper-parameter of the neural network may be stored in the computer readable medium. The hyper-parameter may be a variable varied by a user. The hyper-parameter may include, for example, a learning rate, a cost function, the number of times of repetition of the training cycle, weight initialization (for example, setting of a range of a weight value to be weight-initialized), and the number of hidden units (for example, the number of hidden layers and the number of nodes of the hidden layer). The foregoing data structure is merely an example, and the present disclosure is not limited thereto.

IG. 8 is a simple and general schematic diagram illustrating an example of a computing environment in which the embodiments of the present disclosure are implementable.

The present disclosure has been described as being generally implementable by the computing device, but those skilled in the art will appreciate well that the present disclosure is combined with computer executable commands and/or other program modules executable in one or more computers and/or be implemented by a combination of hardware and software.

In general, a program module includes a routine, a program, a component, a data structure, and the like performing a specific task or implementing a specific abstract data form. Further, those skilled in the art will well appreciate that the method of the present disclosure may be carried out by a personal computer, a hand-held computing device, a microprocessor-based or programmable home appliance (each of which may be connected with one or more relevant devices and be operated), and other computer system configurations, as well as a single-processor or multiprocessor computer system, a mini computer, and a main frame computer.

The embodiments of the present disclosure may be carried out in a distribution computing environment, in which certain tasks are performed by remote processing devices connected through a communication network. In the distribution computing environment, a program module may be located in both a local memory storage device and a remote memory storage device.

The computer generally includes various computer readable media. The computer accessible medium may be any type of computer readable medium, and the computer readable medium includes volatile and non-volatile media, transitory and non-transitory media, and portable and non-portable media. As a non-limited example, the computer readable medium may include a computer readable storage medium and a computer readable transport medium. The computer readable storage medium includes volatile and non-volatile media, transitory and non-transitory media, and portable and non-portable media constructed by a predetermined method or technology, which stores information, such as a computer readable command, a data structure, a program module, or other data. The computer readable storage medium includes a RAM, a Read Only Memory (ROM), an Electrically Erasable and Programmable ROM (EEPROM), a flash memory, or other memory technologies, a Compact Disc (CD)-ROM, a Digital Video Disk (DVD), or other optical disk storage devices, a magnetic cassette, a magnetic tape, a magnetic disk storage device, or other magnetic storage device, or other predetermined media, which are accessible by a computer and are used for storing desired information, but is not limited thereto.

The computer readable transport medium generally implements a computer readable command, a data structure, a program module, or other data in a modulated data signal, such as a carrier wave or other transport mechanisms, and includes all of the information transport media. The modulated data signal means a signal, of which one or more of the characteristics are set or changed so as to encode information within the signal. As a non-limited example, the computer readable transport medium includes a wired medium, such as a wired network or a direct-wired connection, and a wireless medium, such as sound, Radio Frequency (RF), infrared rays, and other wireless media. A combination of the predetermined media among the foregoing media is also included in a range of the computer readable transport medium.

An illustrative environment 1100 including a computer 1102 and implementing several aspects of the present disclosure is illustrated, and the computer 1102 includes a processing device 1104, a system memory 1106, and a system bus 1108. The system bus 1108 connects system components including the system memory 1106 (not limited) to the processing device 1104. The processing device 1104 may be a predetermined processor among various commonly used processors. A dual processor and other multi-processor architectures may also be used as the processing device 1104.

The system bus 1108 may be a predetermined one among several types of bus structure, which may be additionally connectable to a local bus using a predetermined one among a memory bus, a peripheral device bus, and various common bus architectures. The system memory 1106 includes a ROM 1110, and a RAM 1112. A basic input/output system (BIOS) is stored in a non-volatile memory 1110, such as a ROM, an EPROM, and an EEPROM, and the BIOS includes a basic routing helping a transport of information among the constituent elements within the computer 1102 at a time, such as starting. The RAM 1112 may also include a high-rate RAM, such as a static RAM, for caching data.

The computer 1102 also includes an embedded hard disk drive (HDD) 1114 (for example, enhanced integrated drive electronics (EIDE) and serial advanced technology attachment (SATA))—the embedded HDD 1114 being configured for exterior mounted usage within a proper chassis (not illustrated)—a magnetic floppy disk drive (FDD) 1116 (for example, which is for reading data from a portable diskette 1118 or recording data in the portable diskette 1118), and an optical disk drive 1120 (for example, which is for reading a CD-ROM disk 1122, or reading data from other high-capacity optical media, such as a DVD, or recording data in the high-capacity optical media). A hard disk drive 1114, a magnetic disk drive 1116, and an optical disk drive 1120 may be connected to a system bus 1108 by a hard disk drive interface 1124, a magnetic disk drive interface 1126, and an optical drive interface 1128, respectively. An interface 1124 for implementing an outer mounted drive includes, for example, at least one of or both a universal serial bus (USB) and the Institute of Electrical and Electronics Engineers (IEEE) 1394 interface technology.

The drives and the computer readable media associated with the drives provide non-volatile storage of data, data structures, computer executable commands, and the like. In the case of the computer 1102, the drive and the medium correspond to the storage of random data in an appropriate digital form. In the description of the computer readable media, the HDD, the portable magnetic disk, and the portable optical media, such as a CD, or a DVD, are mentioned, but those skilled in the art will well appreciate that other types of computer readable media, such as a zip drive, a magnetic cassette, a flash memory card, and a cartridge, may also be used in the illustrative operation environment, and the predetermined medium may include computer executable commands for performing the methods of the present disclosure.

A plurality of program modules including an operation system 1130, one or more application programs 1132, other program modules 1134, and program data 1136 may be stored in the drive and the RAM 1112. An entirety or a part of the operation system, the application, the module, and/or data may also be cached in the RAM 1112. It will be well appreciated that the present disclosure may be implemented by several commercially usable operation systems or a combination of operation systems.

A user may input a command and information to the computer 1102 through one or more wired/wireless input devices, for example, a keyboard 1138 and a pointing device, such as a mouse 1140. Other input devices (not illustrated) may be a microphone, an IR remote controller, a joystick, a game pad, a stylus pen, a touch screen, and the like. The foregoing and other input devices are frequently connected to the processing device 1104 through an input device interface 1142 connected to the system bus 1108, but may be connected by other interfaces, such as a parallel port, an IEEE 1394 serial port, a game port, a USB port, an IR interface, and other interfaces.

A monitor 1144 or other types of display devices are also connected to the system bus 1108 through an interface, such as a video adaptor 1146. In addition to the monitor 1144, the computer generally includes other peripheral output devices (not illustrated), such as a speaker and a printer.

The computer 1102 may be operated in a networked environment by using a logical connection to one or more remote computers, such as remote computer(s) 1148, through wired and/or wireless communication. The remote computer(s) 1148 may be a work station, a computing device computer, a router, a personal computer, a portable computer, a microprocessor-based entertainment device, a peer device, and other general network nodes, and generally includes some or an entirety of the constituent elements described for the computer 1102, but only a memory storage device 1150 is illustrated for simplicity. The illustrated logical connection includes a wired/wireless connection to a local area network (LAN) 1152 and/or a larger network, for example, a wide area network (WAN) 1154. The LAN and WAN networking environments are general in an office and a company, and make an enterprise-wide computer network, such as an Intranet, easy, and all of the LAN and WAN networking environments may be connected to a worldwide computer network, for example, the Internet.

When the computer 1102 is used in the LAN networking environment, the computer 1102 is connected to the local network 1152 through a wired and/or wireless communication network interface or an adaptor 1156. The adaptor 1156 may make wired or wireless communication to the LAN 1152 easy, and the LAN 1152 also includes a wireless access point installed therein for the communication with the wireless adaptor 1156. When the computer 1102 is used in the WAN networking environment, the computer 1102 may include a modem 1158, is connected to a communication computing device on a WAN 1154, or includes other means setting communication through the WAN 1154 via the Internet. The modem 1158, which may be an embedded or outer-mounted and wired or wireless device, is connected to the system bus 1108 through a serial port interface 1142. In the networked environment, the program modules described for the computer 1102 or some of the program modules may be stored in a remote memory/storage device 1150. The illustrated network connection is illustrative, and those skilled in the art will appreciate well that other means setting a communication link between the computers may be used.

The computer 1102 performs an operation of communicating with a predetermined wireless device or entity, for example, a printer, a scanner, a desktop and/or portable computer, a portable data assistant (PDA), a communication satellite, predetermined equipment or place related to a wirelessly detectable tag, and a telephone, which is disposed by wireless communication and is operated. The operation includes a wireless fidelity (Wi-Fi) and Bluetooth wireless technology at least. Accordingly, the communication may have a pre-defined structure, such as a network in the related art, or may be simply ad hoc communication between at least two devices.

The Wi-Fi enables a connection to the Internet and the like even without a wire. The Wi-Fi is a wireless technology, such as a cellular phone, which enables the device, for example, the computer, to transmit and receive data indoors and outdoors, that is, in any place within a communication range of a base station. A Wi-Fi network uses a wireless technology, which is called IEEE 802.11 (a, b, g, etc.) for providing a safe, reliable, and high-rate wireless connection. The Wi-Fi may be used for connecting the computer to the computer, the Internet, and the wired network (IEEE 802.3 or Ethernet is used). The Wi-Fi network may be operated at, for example, a data rate of 11 Mbps (802.11a) or 54 Mbps (802.11b) in an unauthorized 2.4 and 5 GHz wireless band, or may be operated in a product including both bands (dual bands).

Those skilled in the art may appreciate that information and signals may be expressed by using predetermined various different technologies and techniques. For example, data, indications, commands, information, signals, bits, symbols, and chips referable in the foregoing description may be expressed with voltages, currents, electromagnetic waves, magnetic fields or particles, optical fields or particles, or a predetermined combination thereof.

Those skilled in the art will appreciate that the various illustrative logical blocks, modules, processors, means, circuits, and algorithm operations described in relationship to the embodiments disclosed herein may be implemented by electronic hardware (for convenience, called “software” herein), various forms of program or design code, or a combination thereof. In order to clearly describe compatibility of the hardware and the software, various illustrative components, blocks, modules, circuits, and operations are generally illustrated above in relation to the functions of the hardware and the software. Whether the function is implemented as hardware or software depends on design limits given to a specific application or an entire system. Those skilled in the art may perform the function described by various schemes for each specific application, but it shall not be construed that the determinations of the performance depart from the scope of the present disclosure.

Various embodiments presented herein may be implemented by a method, a device, or a manufactured article using a standard programming and/or engineering technology. A term “manufactured article” includes a computer program, a carrier, or a medium accessible from a predetermined computer-readable storage device. For example, the computer-readable storage medium includes a magnetic storage device (for example, a hard disk, a floppy disk, and a magnetic strip), an optical disk (for example, a CD and a DVD), a smart card, and a flash memory device (for example, an EEPROM, a card, a stick, and a key drive), but is not limited thereto. Further, various storage media presented herein include one or more devices and/or other machine-readable media for storing information.

It shall be understood that a specific order or a hierarchical structure of the operations included in the presented processes is an example of illustrative accesses. It shall be understood that a specific order or a hierarchical structure of the operations included in the processes may be rearranged within the scope of the present disclosure based on design priorities. The accompanying method claims provide various operations of elements in a sample order, but it does not mean that the claims are limited to the presented specific order or hierarchical structure.

The description of the presented embodiments is provided so as for those skilled in the art to use or carry out the present disclosure. Various modifications of the embodiments may be apparent to those skilled in the art, and general principles defined herein may be applied to other embodiments without departing from the scope of the present disclosure. Accordingly, the present disclosure is not limited to the embodiments suggested herein, and shall be interpreted within the broadest meaning range consistent to the principles and new characteristics presented herein.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for designing an integrated circuit performed by a computing device, the method comprising:
identifying devices of a same type arranged in a design area;
dividing a device set including the devices of the same type into a first subset and a second subset;
rearranging a device included in the first subset so that a direction of a pin faces a selected direction, based on the direction of the pin and a location in the design area of the device included in the first subset; and
rearranging a device included in the second subset based on the rearranged device included in the first subset.

2. The method of claim 1, wherein the same type of device is a device included in a same semiconductor device group in the design area.

3. The method of claim 1, wherein the device includes a macro cell configuring an integrated circuit.

4. The method of claim 1, wherein when there are multiple devices of the same type, the devices of the same type are devices in which at least one of a name and a size of the devices is the same.

5. The method of claim 1, wherein the dividing of the device set including the devices of the same type into the first subset and the second subset includes:
classifying the device set into the first subset and the second subset based on location information of each device and the location information of the design area.

6. The method of claim 5, wherein the classifying of the device set into the first subset and the second subset based on the location information of each device and the location information of the design area includes:
classifying devices closest to an edge of the design area in the device set into the first subset; and
classifying the rest of devices other than the first subset in the device set into the second subset.

7. (canceled)

8. (canceled)

9. The method of claim 1, wherein the rearranging of the devices included in the first subset so that the direction of the pin faces the selected direction, based on the direction of the pin and the location in the design area of the device included in the first subset includes:
rearranging the device so that the direction of the pin of the device included in the first subset faces inside of the design area.

10. The method of claim 1, wherein the rearranging of the device included in the second subset among the devices of the same type based on the rearranged device included in the first subset includes:
identifying the direction of the pin of the device included in the first subset; and
rearranging the device included in the second subset based on the direction of the pin of the device included in the first subset.

11. The method of claim 10, wherein the rearranging of the device included in the second subset based on the direction of the pin of the device included in the first subset includes:
sequentially rearranging the device included in the second subset, starting from a device which is neighboring to the device included in the first subset based on the direction of the pin of the device included in the first subset.

12. The method of claim 11, wherein the sequentially rearranging the device included in the second subset, starting from the device which is neighboring to the device included in the first subset based on the direction of the pin of the device included in the first subset includes:
rearranging the device which is neighboring to the device included in the first subset so that a direction of a pin of the device faces outside of the design area;
rearranging a next device so that a direction of a pin of the next device faces inside of the design area if a direction of a pin of an immediately rearranged device faces outside of the design area; and
rearranging the next device so that the direction of the pin of the next device faces outside of the design area if the direction of the pin of the immediately rearranged device faces inside of the design area.

13. A computer program stored in a non-transitory computer readable storage medium, the computer program causing a computing device to perform operations for designing an integrated circuit by a computing device, the operations comprising:
an operation of identifying devices of a same type arranged in a design area;
an operation of dividing a device set including the device of the same type into a first subset and a second subset;
an operation of rearranging a device included in the first subset so that a direction of a pin faces a selected direction, based on the direction of the pin and a location in the design area of the device included in the first subset; and
an operation of rearranging a device included in the second subset based on the rearranged devices included in the first subset.

14. (canceled)

15. (canceled)

16. The computer program of claim 13, wherein the operation of rearranging of the devices included in the first subset so that the direction of the pin faces a selected direction, based on the direction of the pin and the location in the design of the device included in the first subset area includes:
an operation of rearranging the device so that the direction of the pin of the device included in the first subset faces inside of the design area.

17. A computing device, comprising:
a processor including one or more cores; and
a memory,
wherein the processor is configured to:
identify devices of the same type arranged in a design area,
divide a device set including the devices of the same type into a first subset and a second subset,
rearrange a device included in the first subset so that the direction of a pin faces a selected direction, based on the direction of the pin and a location in the design area of the device included in the first subset, and
rearrange a device included in the second subset based on the rearranged devices included in the first subset.

18. (canceled)

19. (canceled)

20. The computing device of claim 17, wherein the rearranging of the devices included in the first subset so that the direction of the pin faces the selected direction, based on the direction of the pin and the location in the design area of the device included in the first subset includes:
rearranging the device so that the direction of the pin of the device included in the first subset faces inside of the design area.
